(19) United States
(12) Patent Application Publication
(10) Pub. No.: US 2026/0319362 A1
(43) Pub. Date: Oct. 15, 2026

(54) PHOTOSENSITIVE ELEMENT, RESIST PATTERN FORMATION METHOD, AND WIRING BOARD PRODUCTION METHOD

(71) Applicant: Resonac Corporation, Tokyo (JP)

(72) Inventors: Yusuke SAKASHITA, Tokyo (JP); Mao NARITA, Tokyo (JP); Tatsuhiko ARAI, Tokyo (JP); Shiho TANAKA, Tokyo (JP); Akiko TAKEDA, Tokyo (JP); Akane ONO, Tokyo (JP)

(73) Assignee: Resonac Corporation, Tokyo (JP)

(21) Appl. No.: 19/479,039

(22) PCT Filed: Apr. 15, 2024
(86) PCT No.: PCT/JP2024/015031

§ 371 Date: Oct. 27, 2025

(51) Int. Cl. G03F 7/031; G03F 7/09; G03F 7/11; H05K 3/06

(52) U.S. Cl. CPC G03F 7/031; G03F 7/094; G03F 7/11; H05K 3/064

(57) ABSTRACT

A photosensitive element according to the present disclosure includes, in this order: a support film; a photosensitive layer; and a protective film, the photosensitive layer contains a binder polymer, a photopolymerizable compound, a photopolymerization initiator, and an anthracene-based sensitizer, the anthracene-based sensitizer includes an anthracene compound having an alkoxy group having 3 or less carbon atoms bonded to 9 and 10-positions of an anthracene ring, and a thickness of the photosensitive layer is equal to or greater than 30 μm, and a light transmittance of the photosensitive layer at a wavelength of 405 nm is equal to or greater than 25.0% and equal to or less than 95.0%.

### TECHNICAL FIELD

The present disclosure relates to a photosensitive element, a method of forming a resist pattern, and a method of manufacturing a wiring substrate.

### BACKGROUND ART

In manufacture of wiring substrates, resist patterns are formed to obtain desired wirings. For formation of the resist patterns, photosensitive elements each including a support film, a layer (hereinafter, also referred to as a “photosensitive layer”) formed on the support film using a photosensitive resin composition, and a protective film laminated on a surface of the photosensitive layer on the side opposite to the support film have widely been used. The resist patterns can be formed by exposing and developing the photosensitive layers.

In recent years, finer wiring formation than before has been required for wiring substrates with size reduction and an increase in density of electronic devices. In order to improve resolution of resist patterns to be formed, anthracene derivatives such as 9,10-dibutoxyanthracene have been studied as sensitizers (see PTL 1, for example).

### CITATION LIST

### Patent Literature

[PTL 1] WO 2007/004619

### SUMMARY OF INVENTION

### Technical Problem

Photosensitive elements used for applications of forming bumps to form copper pillars for connecting TC Chips to semiconductor package wiring substrates have been required to form resist patterns, such as via hole patterns, with high resolution. However, since it is more difficult to uniformly cure photosensitive layers up to their bottom portions as the thicknesses increase, it is difficult to form resist patterns having sufficient resolution and adhesion.

An object of the present disclosure is to provide a photosensitive element capable of forming a resist pattern with excellent resolution and adhesion, a method of forming a resist pattern, and a method of manufacturing a wiring substrate.

### Solution to Problem

The present disclosure provides the following photosensitive element, method of forming a resist pattern, and method of manufacturing a wiring substrate.

[1]A photosensitive element including, in this order: a support film; a photosensitive layer; and a protective film, in which the photosensitive layer contains a binder polymer, a photopolymerizable compound, a photopolymerization initiator, and an anthracene-based sensitizer, the anthracene-based sensitizer includes an anthracene compound having an alkoxy group having 3 or less carbon atoms bonded to 9 and 10-positions of an anthracene ring, and a thickness of the photosensitive layer is equal to or greater than 30 μm, and a light transmittance of the photosensitive layer at a wavelength of 405 nm is equal to or greater than 25.0% and equal to or less than 95.0%.

[2] The photosensitive element according to [1] above, in which the anthracene compound is at least one kind selected from the group consisting of 9,10-dimethoxyanthracene, 9,10-diethoxyanthracene, and 9,10-dipropoxyanthracene.

[3] The photosensitive element according to [1] or [2] above, in which the anthracene compound is 9,10-dimethoxyanthracene or 9,10-diethoxyanthracene.

[4] The photosensitive element according to any one of [1] to [3] above, in which a content of the anthracene-based sensitizer is 0.1 parts by mass to 1.0 parts by mass with respect to 100 parts by mass of a total amount of the binder polymer and the photopolymerizable compound.

[5] The photosensitive element according to any one of [1] to [4] above, in which the protective film is a polyethylene film.

[6]A method of forming a resist pattern, including: forming a photosensitive layer on a substrate using the photosensitive element according to any one of [1] to [5] above; irradiating at least a part of the photosensitive layer with active rays to form a photocured portion; and removing an unphotocured portion of the photosensitive layer from the substrate to form a resist pattern.

[7]A method of manufacturing a wiring substrate, including: performing etching process or plating process on a substrate with a resist pattern formed thereon by the method of forming a resist pattern according to [6] above to form a conductor pattern.

### Advantageous Effects of Invention

According to an aspect of the present disclosure, it is possible to provide a photosensitive element capable of forming a resist pattern with excellent adhesion and resolution. According to another aspect of the present disclosure, it is possible to provide a method of manufacturing a wiring substrate using the photosensitive element.

### BRIEF DESCRIPTION OF DRAWINGS

FIG. 1 is a schematic sectional view illustrating a photosensitive element according to an embodiment.

### DESCRIPTION OF EMBODIMENTS

Hereinafter, a preferred embodiment of the present disclosure will be described in detail with respect to the drawings as needed. It is needless to say that in the following embodiment, components (including elemental steps and the like) are not necessarily essential unless otherwise specified and considered essential in principle. The same applies to numerical values and ranges which should not be construed as unreasonably limiting the present disclosure.

In the present specification, the term “process” includes not only an independent process but also a process that cannot be clearly distinguished from other processes as long as a prescribed effect of the process is achieved. The term “layer” includes not only a structure with a shape formed on an entire surface but also a structure with a shape formed on a part of the surface in observation in a plan view.

A numerical range of “equal to or greater than A” means A and a range of greater than A. A numerical range of “equal to or less than A” means A and a range of less than A. Numerical ranges indicated using “to” indicate ranges including the numerical values stated before and after “to” as the minimum and maximum values, respectively. In numerical ranges stated in stages in the present specification, an upper limit value or a lower limit value of a numerical range in a certain stage can be arbitrarily combined with an upper limit value or a lower limit value of a numerical range in another stage. In a numerical range described in the present specification, an upper limit value or a lower limit value of the numerical range may be replaced with a value described in Examples. It is only necessary for “A or B” to include either A or B, and both A and B may also be included. One kind of materials exemplified in the present specification can be used alone, or two or more kinds thereof can be used in combination unless otherwise particularly stated.

As used in the present specification, “(meth)acrylic acid” means at least either “acrylic acid” or “methacrylic acid” corresponding thereto. The same applies to other similar expressions such as “(meth)acrylate”. A “(poly)oxyethylene group” means an oxyethlene group or a polyoxyethylene group in which two or more ethylene groups are linked by an ether bond. A “(poly)oxypropylene group” means an oxypropylene group or a polyoxypropylene group in which two or more propylene groups are linked by an ether bond. “EO-modified” means a compound having a (poly)oxyethylene group. “PO-modified” means a compound having a (poly)oxypropylene group. “EO/PO-modified” means a compound having a (poly)oxyethylene group and/or a (poly)oxypropylene group.

In the present specification, in a case where a plurality of substances corresponding to each component are present in a composition, the amount of each component in a composition means the total amount of the plurality of substances that are present in the composition unless otherwise particularly specified. In the present specification, the term “solid content” refers to a nonvolatile part from which substances that volatilize (water, a solvent, and the like) are excluded in the photosensitive resin composition. In other words, “solid content” refers to substances, which remain without volatilization after drying of the photosensitive resin composition described later, other than the solvent and also includes components in a liquid form, a starch syrupy-like form, or a wax form at a room temperature (25° C.).

### [Photosensitive Element]

The photosensitive element according to the present embodiment includes, in this order: a support film; a photosensitive layer; and a protective film. The photosensitive layer contains (A) a binder polymer, (B) a photopolymerizable compound, (C) a photopolymerization initiator, and (D) an anthracene-based sensitizer, and the anthracene-based sensitizer includes an anthracene compound having an alkoxy group having three or less carbon atoms bonded to 9 and 10-positions of an anthracene ring. The thickness of the photosensitive layer is equal to or greater than 30 μm, and a light transmittance of the photosensitive layer at a wavelength of 405 nm is equal to or greater than 25.0% and equal to or less than 95.0%.

### (Photosensitive Layer)

The photosensitive layer is a layer formed using a photosensitive resin composition containing a binder polymer, a photopolymerizable compound, a photopolymerization initiator, and an anthracene-based sensitizer. The photosensitive resin composition according to the present embodiment may further contain a polymerization inhibitor or other components as needed. Each component will be described below.

### ((A) Binder Polymer)

The photosensitive resin composition contains a binder polymer as a component (A). The component (A) can have a polymerizable monomer as a monomer unit (structural unit) and can be obtained through radical polymerization of a polymerizable monomer, for example.

Examples of the polymerizable monomer include (meth)acrylic acid, hydroxyalkyl (meth)acrylate, benzyl (meth)acrylate, styrene compounds (styrene or styrene derivatives), alkyl (meth)acrylate, tetrahydrofurfuryl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, (meth)acrylamide (such as diacetone (meth)acrylamide), (meth)acrylonitrile, ethers of vinyl alcohol (such as vinyl-n-butyl ether), α-bromo(meth)acrylic acid, α-chloro(meth)acrylic acid, β-furyl(meth)acrylic acid, β-styryl(meth)acrylic acid, maleic acid, maleic anhydride, maleic acid monoesters (such as monomethyl maleate, monoethyl maleate, and monoisopropyl maleate), fumaric acid, cinnamic acid, α-cyanocinnamic acid, itaconic acid, crotonic acid, and propiolic acid.

The component (A) may include (meth)acrylic acid as a monomer unit from the viewpoint of enhancing alkali developability. The content of (meth)acrylic acid in the component (A) may be equal to or greater than 1% by mass, equal to or greater than 10% by mass, equal to or greater than 15% by mass, equal to or greater than 20% by mass, equal to or greater than 23% by mass, or equal to or greater than 25% by mass and may be equal to or less than 50% by mass, equal to or less than 45% by mass, equal to or less than 40% by mass, equal to or less than 35% by mass, or equal to or less than 30% by mass with respect to the total amount of monomer units constituting the component (A). The content of the monomer unit of (meth)acrylic acid may be 1% by mass to 50% by mass, 10% by mass to 45% by mass, 15% by mass to 45% by mass, 20% by mass to 40% by mass, 23% by mass to 35% by mass, or 25% by mass to 30% by mass, for example, from these viewpoints.

The component (A) may include a hydroxyalkyl (meth)acrylate as a monomer unit from the viewpoint of enhancing alkali developability. Examples of hydroxyalkyl (meth)acrylate include hydroxymethyl (meth)acrylate, hydroxyethyl (meth)acrylate, hydroxypropyl (meth)acrylate, hydroxybutyl (meth)acrylate, hydroxypentyl (meth)acrylate, and hydroxyhexyl (meth)acrylate.

The content of hydroxyalkyl (meth)acrylate in the component (A) may be equal to or greater than 0.1% by mass, equal to or greater than 0.5% by mass, equal to or greater than 1.0% by mass, equal to or greater than 1.5% by mass, equal to or greater than 2.0% by mass, equal to or greater than 2.5% by mass, or equal to or greater than 3.0% by mass and may be equal to or less than 20% by mass, equal to or -less than 15% by mass, equal to or less than 10% by mass, equal to or less than 5.0% by mass, equal to or less than 4.0% by mass, or equal to or less than 3.0% by mass with respect to the total amount of the monomer units constituting the component (A). The content of the monomer unit of hydroxyalkyl (meth)acrylate may be 0.1% by mass to 20% by mass, 0.5% by mass to 15% by mass, 1.0% by mass to 10% by mass, 1.5% by mass to 5.0% by mass, 2.0% by mass to 4.0% by mass, or 2.5% by mass to 3.0% by mass, for example, from these viewpoints.

The component (A) may include styrene or a styrene derivative as a monomer unit from the viewpoint of forming a resist pattern with more excellent resolution. Examples of the styrene derivative include vinyltoluene and α-methylstyrene.

The content of the styrene or the styrene derivative in the component (A) may be equal to or greater than 30% by mass, equal to or greater than 32% by mass, equal to or greater than 35% by mass, equal to or greater than 40% by mass, or equal to or greater than 42% by mass and may be equal to or less than 70% by mass, equal to or less than 65% by mass, equal to or less than 60% by mass, equal to or less than 55% by mass, or equal to or less than 50% by mass with respect to the total amount of the monomer units constituting the component (A). The content of the monomer unit of the styrene compound may be 30% by mass to 70% by mass, 32% by mass to 65% by mass, 35% by mass to 60% by mass, 40% by mass to 55% by mass, or 42% by mass to 50% by mass, for example, from these viewpoints.

The component (A) may include benzyl (meth)acrylate as a monomer unit from the viewpoint of achieving satisfactory adhesion and a peeling property of the resist pattern. The content of benzyl (meth)acrylate in the component (A) may be equal to or greater than 5% by mass, equal to or greater than 10% by mass, or equal to or greater than 15% by mass and may be equal to or less than 40% by mass, equal to or less than 35% by mass, equal to or less than 30% by mass, or equal to or less than 25% by mass with respect to the total amount of the monomer units constituting the component (A). The content of the monomer unit of benzyl (meth)acrylate may be 5% by mass to 40% by mass, 5% by mass to 35% by mass, 10% by mass to 30% by mass, 10% by mass to 25% by mass, or 15% by mass to 25% by mass, for example, from these viewpoints.

The component (A) may further include structural units derived from other monomers in addition to the above-described monomers. Examples of other monomers may include (meth)acrylic acid esters. Examples of (meth)acrylic acid esters include (meth)acrylic acid alkyl ester, (meth)acrylic acid cycloalkyl ester, and (meth)acrylic acid aryl ester.

Preferably, other monomers may be (meth)acrylic acid alkyl ester from the viewpoint of improving alkali developability and a peeling property. An alkyl group of (meth)acrylic acid alkyl ester may be, for example, a methyl group, an ethyl group, a propyl group, a butyl group, a pentyl group, a hexyl group, a heptyl group, an octyl group, a nonyl group, a decyl group, an undecyl group, a dodecyl group, or a structural isomer thereof, or from the viewpoint of further improving the peeling property, the alkyl group may be an alkyl group having 1 to 4 carbon atoms.

The acid value of the component (A) may be equal to or greater than 100 mgKOH/g, equal to or greater than 120 mgKOH/g, equal to or greater than 140 mgKOH/g, equal to or greater than 150 mgKOH/g, equal to or greater than 160 mgKOH/g, or equal to or greater than 170 mgKOH/g from the viewpoint that it is possible to achieve suitable development and may be equal to or less than 250 mgKOH/g, equal to or less than 240 mgKOH/g, equal to or less than 230 mgKOH/g, equal to or less than 200 mgKOH/g, or equal to or less than 190 mgKOH/g from the viewpoint of improving adhesion (developer resistance) of a cured article of the photosensitive resin composition. The acid value of the component (A) can be adjusted by the content of the structural units constituting the component (A) (for example, the structural unit derived from (meth)acrylic acid).

The acid value can be measured by the following procedure. First, 1 g of binder polymer as a target of measurement of the acid value is accurately weighed, and 30 g of acetone is then added to the binder polymer to uniformly dissolve the binder polymer and to thereby obtain a solution. Then, an appropriate amount of phenolphthalein, which is an indicator, is added to the solution, and titration is then performed using an aqueous solution of 0.1 N of potassium hydroxide (KOH). The acid value is obtained by calculating the mass (unit: mg) of KOH required to neutralize the acetone solution of the binder polymer.

The weight average molecular weight (Mw) of the component (A) may be equal to or greater than 10000, equal to or greater than 20000, equal to or greater than 25000, or equal to or greater than 30000 from the viewpoint that excellent adhesion (developer resistance) of the cured article of the photosensitive resin composition is achieved and may be equal to or less than 100000, equal to or less than 80000, equal to or less than 60000, equal to or less than 50000, or equal to or less than 40000 from the viewpoint that it is possible to achieve suitable development. The dispersity (Mw/Mn) of the component (A) may be equal to or greater than 1.0 or equal to or greater than 1.5, for example, and may be equal to or less than 3.0 or equal to or less than 2.5 from the viewpoint of further improving adhesion and resolution.

The weight average molecular weight and the dispersity can be measured by gel permeation chromatography (GPC) using a standard polystyrene calibration curve. GPC conditions are as follows.
Pump: Hitachi L-6000 model. (manufactured by Hitachi, Ltd., trade name)
Columns: Gelpack GL-R420, Gelpack GL-R430, Gelpack GL-R440 (these are all manufactured by Resonac Corporation, trade name)
Eluent: Tetrahydrofuran
Measurement temperature: 40° C.
Flow rate: 2.05 mL/min
Detector: Hitachi L-3300 model RI (manufactured by Hitachi, Ltd., trade name)

The content of the component (A) may be equal to or greater than 20% by mass, equal to or greater than 30% by mass, or equal to or greater than 40% by mass from the viewpoint of excellent film moldability and may be equal to or less than 90% by mass, equal to or less than 80% by mass, or equal to or less than 65% by mass from the viewpoint of further excellent sensitivity and resolution with respect to the total amount of solid content of the photosensitive resin composition.

The content of the component (A) may be equal to or greater than 30 parts by mass, equal to or greater than 35 parts by mass, or equal to or greater than 40 parts by mass from the viewpoint of excellent film moldability and may be equal to or less than 70 parts by mass, equal to or less than 65 parts by mass, or equal to or less than 60 parts by mass from the viewpoint of further improving sensitivity and resolution with respect to 100 parts by mass of the total amount of the component (A) and the component (B).

### (Photopolymerizable Compound (B))

The photosensitive resin composition contains a photopolymerizable compound as a component (B). The component (B) may be any compound that is polymerized by light and may be, for example, a compound having an ethylenic unsaturated bond. The component (B) may include a multifunctional monomer having two or more reactive groups that reacts by radicals. The component (B) may include bisphenol A type (meth)acrylate from the viewpoint of improving alkali developability, resolution, and releasability after curing.

Examples of bisphenol A type (meth)acrylate include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-(meth)acryloxypolyethoxy polypropoxy)phenyl)propane. The component (B) may include 2,2-bis(4-((meth)acryloxypolyethoxy)phenyl)propane or may include 2,2-bis(4-((meth)acryloxypentaethoxy)phenyl)propane from the viewpoint of further improving resolution and releasability.

The content of the bisphenol A type (meth)acrylate may be equal to or greater than 20% by mass, equal to or greater than 30% by mass, or equal to or greater than 40% by mass and may be equal to or less than 100% by mass, equal to or less than 95% by mass, or equal to or less than 90% by mass with respect to the total amount of the component (B) from the viewpoint of further improving resolution.

The component (B) may include an α,β-unsaturated ester compound obtained by causing α,β-unsaturated carboxylic acid to react with a polyhydric alcohol from the viewpoint of further suitably improving resolution and flexibility. Examples of the α,β-unsaturated ester compound include polyethylene glycol di(meth)acrylate, polypropylene glycol di(meth)acrylate, polyalkylene glycol di(meth)acrylates such as EO-modified polypropylene glycol, trimethylolpropane di(meth)acrylate, trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, tetramethylolmethane tri(meth)acrylate, and tetramethylolmethane tetra(meth)acrylate.

The component (B) may include a compound having three or more (meth)acryloyl groups from the viewpoint of improving sensitivity and adhesion. Examples of such a compound include trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, EO-modified pentaerythritol tetra(meth)acrylate, EO-modified ditrimnethylolpropane tetra(meth)acrylate, and EO-modified dipentaerythritol hexa(meth)acrylate.

The content of the α,β-unsaturated ester compound may be equal to or greater than 20% by mass or equal to or greater than 30% by mass from the viewpoint of improving flexibility and may be equal to or less than 70% by mass or equal to or less than 60% by mass from the viewpoint of further improving resolution with respect to the total amount of the component (B).

The photosensitive resin composition may include photopolymerizable compounds other than bisphenol A-based (meth)acrylate and the α,β-unsaturated ester compound as components (B).

Examples of other photopolymerizable compounds include nonylphenoxypolyethylene oxyacrylate, a phthalic acid compound, (meth)acrylic acid alkyl ester, and a photopolymerizable compound (such as an oxetane compound) having at least one cation polymerizable cyclic ether group in a molecule. Other photopolymerizable compounds may be at least one kind selected from the group consisting of nonylphenoxypolyethylene oxyacrylate and a phthalic acid compound from the viewpoint of further suitably improving resolution, adhesion, the resist shape, and a peeling property after curing.

Examples of nonylphenoxypolyethylene oxyacrylate include nonylphenoxytriethylene oxyacrylate, nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate, and nonylphenoxyundecaethylene oxyacrylate.

Examples of the phthalic acid-based compound include γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate.

In a case where the component (B) includes other photopolymerizable compounds, the content of other photopolymerizable compounds may be equal to or greater than 1% by mass, equal to or greater than 3% by mass, or equal to or greater than 5% by mass and may be equal to or less than 30% by mass, equal to or less than 25% by mass, or equal to or less than 20% by mass with respect to the total amount of the components (B) from the viewpoint of further suitably improving resolution, adhesion, the resist shape, and a peeling property after curing.

The content of the component (B) may be 20 parts by mass to 60 parts by mass, 30 parts by mass to 55 parts by mass, or 35 parts by mass to 50 parts by mass from the viewpoint of further improving sensitivity and resolution with respect to 100 parts by mass of the total amount of the component (A) and the component (B).

### (Photopolymerization Initiator (C))

The photosensitive resin composition contains a photopolymerization initiator as a component (C). The component (C) is not particularly limited as long as the component can polymerize the component (B), and the component (C) can be appropriately selected from typically used photopolymerization initiators.

Examples of the component (C) include: hexaarylbiimidazole compounds; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-1-butanone, 4-(2-hydroxyethoxy)phenyl-2-(hydroxy-2-propyl)ketone, and 2-methyl-1-[4-(methylthio)phenyl]-2-morpholino-propanone-1; quinones such as alkylanthraquinone; benzoin ether compounds such as benzoin alkyl ether; benzoin compounds such as benzoin and alkylbenzoin; benzyl derivatives such as benzyldimethyl ketal; and phosphine oxide compounds such as bis(2,4,6-trimethylbenzoyl)-phenylphosphine oxide, bis(2,6-dimethylbenzoyl)-2,4,4-trimethyl-pentylphosphine oxide, and (2,4,6-trimethylbenzoyl)ethoxyphenylphosphine oxide.

The component (C) may include a hexaarylbiimidazole compound from the viewpoint of suppressing permeation of the component (D) into the polyethylene film. An aryl group in the hexaarylbiimidazole compound may be a phenyl group or the like. The hydrogen atom bonded to the aryl group in the hexaarylbiimidazole compound may be substituted with a halogen atom (such as a chlorine atom).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer. The hexaarylbiimidazole compound is preferably 2-(o-chlorophenyl)-4,5-diphenylimidazole dimer, and is more preferably 2,2-bis(o-chlorophenyl)-4, 5-4′, 5′-tetraphenyl-1,2′-biimidazole from the viewpoint of further suppressing permeation of the component (D) into the polyethylene film.

The content of the hexaarylbiimidazole compound may be equal to or greater than 90% by mass, equal to or greater than 95% by mass, or equal to or greater than 99% by mass with respect to the total amount of the component (C) from the viewpoint that it is possible to further suppress permeation of the component (D) into the polyethylene film. The component (C) may consist only of the hexaarylbiimidazole compound.

The content of the component (C) may be 1.0 parts by mass to 20 parts by mass, 2.0 parts by mass to 15 parts by mass, 3.0 parts by mass to 10 parts by mass, or 4.0 parts by mass to 8.0 parts by mass with respect to 100 parts by mass of the total amount of the component (A) and the component (B). It becomes easy to improve both sensitivity and resolution with a satisfactory balance when the content of the component (C) falls within the range.

### ((D) Anthracene-based Sensitizer)

The photosensitive resin composition can effectively utilize an absorption wavelength of the active rays used for exposure by containing an anthracene-based sensitizer as a component (D). The component (D) includes an anthracene compound having an anthracene ring and an alkoxy group having 3 or less carbon atoms bonded to the 9 and 10-positions of the anthracene ring.

It is possible to suppress migration of the component (D) from the photosensitive layer to the polyethylene film in a case where the protective film is a polyethylene film, by using the anthracene compound having the specific structure as the component (D). On the other hand, in a case where an anthracene compound (for example, 9,10-dibutoxyanthracene) in which an alkoxy group having 4 or more carbon atoms is bonded to the 9 and 10-positions of the anthracene ring is used, migration to the polyethylene film is likely to occur. The present inventors have presumed that the reason therefor is because the alkoxy group having 3 or less carbon atoms is less hydrophobic than the alkoxy group having 4 or more carbon atoms and the component (D) is thus less likely to permeate into the hydrophobic polyethylene film. Also, since the amount of component (D) substantially included in the photosensitive layer becomes unlikely to decrease by using the anthracene compound with excellent migration resistance as the component (D), it is possible to improve sensitivity of the photosensitive layer.

The alkoxy group having 3 or less carbon atoms may be a methoxy group, an ethoxy group, or a propoxy group. The hydrogen atoms constituting the anthracene ring may be substituted by at least one kind of group selected from the group consisting of an alkyl group (for example, an alkyl group having 1 to 12 carbon atoms), a halogeno group, a cyano group, a carboxy group, a phenyl group, an alkoxycarbonyl (for example, an alkoxycarbonyl group having 2 to 6 carbon atoms), and a benzoyl group.

Examples of the component (D) include 9,10-dimethoxyanthracene, 9,10-diethoxyanthracene, and 9,10-dipropoxyanthracene. The component (D) may include at least one kind selected from the group consisting of 9,10-dimethoxyanthracene, 9,10-diethoxyanthracene, and 9,10-dipropoxyanthracene for more excellent migration resistance, and preferably includes 9,10-dimethoxyanthracene or 9,10-diethoxyanthracene.

The content of the component (D) is preferably equal to or greater than 0.1 parts by mass, is more preferably equal to or greater than 0.15 parts by mass, is further preferably equal to or greater than 0.2 parts by mass, and is particularly preferably equal to or greater than 0.25 parts by mass from the viewpoint of further improving sensitivity, adhesion, and resolution with respect to 100 parts by mass of the total amount of the component (A) and the component (B). The content of the component (D) is preferably equal to or less than 1.0 parts by mass, is more preferably equal to or less than 0.8 parts by mass, is further preferably equal to or less than 0.7 parts by mass, and is particularly preferably equal to or less than 0.6 parts by mass from the viewpoint of achieving satisfactory storage stability of the photosensitive element. The content of the component (D) may be 0.1 parts by mass to 1.0 parts by mass, 0.15 parts by mass to 0.8 parts by mass, 0.2 parts by mass to 0.7 parts by mass, or 0.25 parts by mass to 0.6 parts by mass from the above-described viewpoints.

The photosensitive resin composition according to the present embodiment allows any sensitizing aid such as a naphthalene compound not to be used together and enables a resist pattern with excellent resolution to be formed by containing the anthracene compound having a specific structure as the component (D).

### ((E) Polymerization Inhibitor)

The photosensitive resin composition may further contain a polymerization inhibitor as a component (E) from the viewpoint of suppressing polymerization at the unexposed portion at the time of formation of the resist pattern and further improving resolution. Examples of the polymerization inhibitor include 4-tert-butylcatechol and 4-hydroxy-2,2,6,6-tetramethylpiperidine-N-oxyl.

The content of the component (E) may be equal to or greater than 0.001 parts by mass, equal to or greater than 0.005 parts by mass, or equal to or greater than 0.01 parts by mass from the viewpoint of sensitivity and resolution and may be equal to or less than 0.10 parts by mass, equal to or less than 0.08 parts by mass, or equal to or less than 0.05 parts by mass from the viewpoint of sensitivity and adhesion with respect to 100 parts by mass of the total amount of the component (A) and the component (B).

### (Other Components)

The photosensitive resin composition may further contain one or more kinds of components other than the components described above. Examples of other components include a hydrogen donor (such as bis[4-(dimethylamino)phenyl]methane, bis[4-(diethylamino)phenyl]methane, N-phenylglycine, or the like), a dye (such as malachite green), tribromophenyl sulfone, a photochromic agent (leuco crystal violet), a heat color stabilizer, a plasticizer (such as p-toluenesulfonamide), a pigment, a filler, a defoaming agent, a flame retardant, a stabilizer, an adhesion-imparting agent, a leveling agent, a stripping accelerator, an antioxidant, a fragrance, an imaging agent, and a thermal crosslinker. The content of other components may be egual to or greater than 0.005 parts by mass or equal to or greater than 0.01 parts by mass and may be equal to or less than 20 parts by mass or equal to or less than 10 parts by mass with respect to 100 parts by mass of the total amount of the component (A) and the component (B).

The photosensitive resin composition may further contain one or more kinds of organic solvents from the viewpoint of adjusting viscosity. Examples of the organic solvent include methanol, ethanol, acetone, methyl ethyl ketone, methyl cellosolve, ethyl cellosolve, toluene, N,N-dimethylformamide and propylene glycol monomethyl ether. The photosensitive resin composition can be used as a solution (hereinafter, referred to as an “application liquid”) with a soli content (nonvolatile part) of about 30% by mass to 60% by mass by dissolving the above-described components in the organic solvent, for example. The solid content means the remaining components after volatile components are removed from the solution of the photosensitive resin composition.

The light transmittance of the photosensitive layer at a wavelength of 405 nm is equal to or greater than 25.0% and equal to or less than 95.0%. When the light transmittance of the photosensitive layer at the wavelength of 405 nm is equal to or greater than 25.0%, sufficient crosslinking density is likely to be obtained even at the bottom portion of the resist pattern, and degradation of the resist shape can be suppressed. The light transmittance may be equal to or greater than 28.0%, equal to or greater than 30.0%, equal to or greater than 32.0%, or equal to or greater than 33.0%. When the light transmittance of the photosensitive layer at the wavelength of 405 nm is equal to or less than 95.0%, light reflected from the bottom portion of the resist pattern can be suppressed, occurrence of the resist sidewall is suppressed, and satisfactory resolution can be achieved. The light transmittance may be equal to or less than 90.0%, equal to or less than 80.0%, equal to or less than 70.0%, or equal to or less than 60.0%.

As the light transmittance of the photosensitive layer at the wavelength of 405 nm, measurement was performed on the support film with the photosensitive layer formed thereon using a spectrophotometer U-3310 (manufactured by Hitachi High-Tech Corporation). The value was obtained by performing the measurement by setting measurement conditions of a slit of 2 nm, a scan speed of 300 nm/min, and a measurement range of 750 nm to 200 nm. It is possible to calculate the light transmittance of the photosensitive layer by converting the result of measurement performed using only the support film as a reference. The light transmittance measured by the above-described method is a value calculated to include the amount of light scattered by the photosensitive layer and the support film, that is, it is possible to state that the light transmittance is a value with no baseline correction by scattered light. The light transmittance at the wavelength of 405 nm is derived from the absorbance of the component (D), and it is possible to adjust the light transmittance of the photosensitive layer at the wavelength of 405 nm by the structure and the content of the component (D). The light transmittance can also be measured with reference to JIS K 0115 (2004).

The thickness of the photosensitive layer after the drying (after the organic solvent is volatilized in a case where the photosensitive resin composition contains the organic solvent) may be 30 μm to 100 μm. The thickness of the photosensitive layer may be equal to or greater than 30 μm, equal to or greater than 35 μm, equal to or greater than 38 μm, equal to or greater than 40 μm, or equal to or greater than 45 μm from the viewpoint of forming a resist pattern with a high aspect ratio and may be equal to or less than 100 μm, equal to or less than 90 μm, equal to or less than 80 μm, equal to or less than 70 μm, or equal to or less than 60 μm from the viewpoint of releasability.

### (Support Film)

As the support film, a polymer film having heat resistance and solvent resistance can be used. Examples of the support film include polyester films such as a polyethylene terephthalate film (PET), a polybutylene terephthalate (PBT), and polyethylene-2,6-naphthalate (PEN), and polyolefin films such as a polyethylene film and a polypropylene film.

The haze of the support film may be 0.01% to 5.0%, 0.01% to 1.5%, 0.01% to 1.0%, or 0.01% to 0.5%. The haze can be measured using a commercially available cloudiness meter (turbidimeter) in accordance with the method specified in JIS K7105. The haze can be measured with a commercially available turbidimeter such as NDH-5000 (manufactured by Nippon Denshoku Industries Co., Ltd., trade name), for example.

The thickness of the support film may be equal to or greater than 1 μm, equal to or greater than 5 μm, or equal to or greater than 10 μm from the viewpoint of easiness of suppressing breakage of the support film when the support film is peeled off from the photosensitive layer. The thickness of the support film may be equal to or less than 100 μm, equal to or less than 50 μm, equal to or less than 30 μm, or equal to or less than 20 μm from the viewpoint of easiness of suitable exposure in a case where exposure is performed via the support film.

### (Protective Film)

Examples of the protective film include polyester films such as a polyethylene terephthalate film and polyolefin films such as a polyethylene film and a polypropylene film. The polyethylene film tends to be less likely to cause static electricity than the polyethylene terephthalate film, the polypropylene film, and the like. It is possible to suppress winding deviation of the photosensitive element by using the polyethylene film as the protective film, and it is possible to suppress breakage of the photosensitive layer since static electricity is less likely to be caused when the protective film is peeled off from the photosensitive layer.

The thickness of the protective film may be equal to or greater than 1 μm, equal to or greater than 5 μm, equal to or greater than 10 μm, equal to or greater than 15 μm, or equal to or greater than 20 μm from the viewpoint of easiness of suppressing breakage of the protective film when the photosensitive layer and the support film are laminated on the substrate while the protective film is peeled off. From the viewpoint of easiness of improving productivity, the thickness may be equal to or less than 100 μm, equal to or less than 50 μm, equal to or less than 40 μm, equal to or less than 35 μm, or equal to or less than 30 μm.

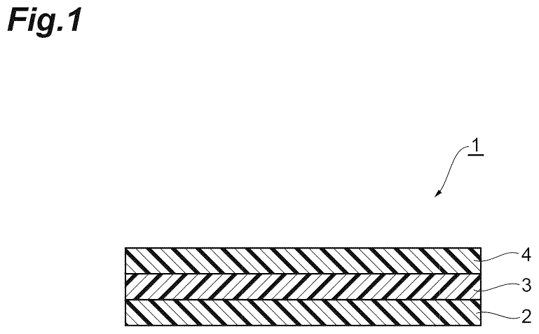

FIG. 1 is a schematic sectional view illustrating a photosensitive element according to an embodiment of the present invention. A photosensitive element 1 includes a support film 2, a photosensitive layer 3 provided on the support film 2, and a protective film 4 provided on the photosensitive layer 3 on the side opposite to the support film 2 as illustrated in FIG. 1.

The photosensitive element 1 can be obtained, for example, in the following manner. First, the photosensitive layer 3 is formed on the support film 2. The photosensitive layer 3 can be formed by, for example, applying the photosensitive resin composition containing the organic solvent to form a coating layer and drying the coating layer. Next, the protective film 4 is formed on the surface of the photosensitive layer 3 on the side opposite to the support film 2.

The coating layer is formed by a known method such as roll coating, comma coating, gravure coating, air knife coating, die coating, or bar coating, for example. The drying of the coating layer is performed such that the amount of organic solvent remaining in the photosensitive layer 3 becomes equal to or less than 2% by mass, for example, and specifically, the drying is performed at 70° C. to 150° C. for 5 minutes to 30 minutes, for example.

The photosensitive element may further include other layers such as a cushion layer, an adhesive layer, a light absorbing layer, and a gas barrier layer in another embodiment.

The photosensitive element 1 may be in the sheet form or in a form of a photosensitive element roll wound around a winding core in a roll shape, for example. In the photosensitive element roll, the photosensitive element 1 is preferably wound such that the support film 2 is located outside. The winding core is formed of, for example, polyethylene, polypropylene, polystyrene, polyvinyl chloride, or an acrylonitrile-butadiene-styrene copolymer. An end surface of the photosensitive element roll may be provided with an end surface separator from the viewpoint of protecting the end surface or may be provided with a moisture-proofing end surface separator from the viewpoint of edge fusion resistance. The photosensitive element 1 may be wrapped by, for example, a black sheet having low moisture permeability.

The photosensitive element 1 can be suitably used for forming a resist pattern and can be particularly suitably used in a method of manufacturing a wiring substrate, which will be described later.

### [Method of Forming Resist Pattern]

A method of forming a resist pattern according to the present embodiment may include: a process of forming a Photosensitive layer on a substrate using the above-described photosensitive element (photosensitive layer formation process); a process of irradiating at least a part (predetermined part) of the photosensitive layer with active rays to form a photocured portion (exposure process); and a process of removing at least a part of the above-described unphotocured portion from the substrate (development process), and the method may further include other processes as needed. The resist pattern may be referred to as a photocured product pattern of the photosensitive resin composition or may be referred to as a relief pattern. The method of forming the resist pattern may also be referred to as a method of manufacturing a resist patterned substrate.

### (Photosensitive Layer Formation Process)

In the photosensitive layer formation process, a photosensitive layer is formed on a substrate using the above-described photosensitive element. Although the substrate is not particularly limited, a circuit formation substrate including an insulating layer and a conductor layer formed on the insulating layer or a die pad (lead frame base material) such as an alloy base material is typically used.

As a method of forming the photosensitive layer on the substrate, it is possible to form the photosensitive layer on the substrate by removing the protective film and then pressure-bonding the photosensitive layer of the photosensitive element to the substrate while heating the photosensitive layer, for example. As a result, a laminate including the substrate, the photosensitive layer, and the support film in this order is obtained.

The photosensitive layer formation process may be carried out under a reduced pressure from the standpoint of adhesion and followability. Although the heating at the time of the pressure-bonding may be performed at a temperature of 70° C. to 130° C., and the pressure-bonding may be performed at a pressure of 0.1 MPa to 1.0 MPa (1 kgf/cm² to 10 kgf/cm²), these conditions can be appropriately selected as needed. Although it is not necessary to perform preheating process on the substrate in advance as long as the photosensitive layer of the photosensitive element is heated to 70° C. to 130° C., it is also possible to perform preheating of the substrate in order to further improve adhesion and followability.

### (Exposure Process)

In the exposure process, the photosensitive layer is exposed to active rays through the support film. In this manner, the exposed portion irradiated with the active rays is photocured to thereby form a photocured portion (latent image).

As an exposure method, a known exposure scheme can be applied, and examples thereof include a method of performing imagewise irradiation with active rays via a negative or positive mask pattern called an art work (mask exposure scheme), a method of performing imagewise irradiation via a lens using active rays caused to project an image of a photomask (projection exposure scheme), and a method of performing imagewise irradiation with active rays such as a laser direct imaging (LDI) exposure method or a digital light processing (DLP) exposure method (direct drawing exposure scheme).

A light source of the active rays is not particularly limited as long as it is a known light source that is usually used, and examples of the light source to be used include light sources that effectively emit ultraviolet rays, such as gas lasers such as a carbon arc lamp, a mercury vapor arc lamp, an ultra-high pressure mercury lamp, a high pressure mercury lamp, a xenon lamp and an argon laser, solid lasers such as a YAG laser, and semiconductor lasers such as a gallium nitride-based blue-violet laser. Among these, a light source capable of emitting i-line monochromatic light having a wavelength of 365 nm, a light source capable of emitting h-line monochromatic light having a wavelength of 405 nm, or a light source capable of emitting active rays having an exposure wavelength of an ihg mixed line may be used from the viewpoint of improving resolution and an alignment property with a satisfactory balance.

### (Post-Exposure Thermal Treatment Process)

In the method of forming a resist pattern according to the present embodiment, post exposure bake (PEB) may be performed after the exposure process and before the development process from the viewpoint of improving adhesion. The temperature for performing the PEB may be 50° C. to 100° C. As a heating machine, a hot plate, a box dryer, a heating roll, or the like may be used.

### (Development Process)

In the development process, the uncured portion of the photosensitive layer is removed from the substrate after the support film is peeled off. Through the development process, a resist pattern constituted by the photocured portion obtained by photocuring the photosensitive layer is formed on the substrate. A developing method may be wet development or dry development and is preferably wet development.

In the case of wet development, development can be performed by a known wet developing method using a developer corresponding to the photosensitive resin composition. Examples of the wet developing method include a dipping scheme, a puddling scheme, a high-pressure spraying scheme, and methods using brushing, scrubbing, and rocking immersion. One kind of these wet developing methods may be used alone, or two or more kinds of the methods may be used in combination to achieve the development.

The developer is appropriately selected in accordance with the configuration of the photosensitive resin composition. Examples of the developer include an alkaline aqueous solution and an organic solvent developer.

From the standpoint of safety, stability, and satisfactory operability, an alkaline aqueous solution may be used as the developer. Examples of a base in the alkaline aqueous solution to be used include alkali hydroxides such as lithium, sodium, or potassium hydroxides, alkali carbonates such as lithium, sodium, potassium, or ammonium carbonates or bicarbonates, alkali metal phosphates such as potassium phosphate or sodium phosphate, alkali metal pyrophosphates such as sodium pyrophosphate and potassium pyrophosphate, sodium borate, sodium metasilicate, tetramethylammonium hydroxide, ethanolamine, ethylene diamine, diethylenetriamine, 2-amino-2-hydroxymethyl-1,3-propanediol, 1,3-diamino-2-propanol, and morpholine.

Examples of the alkaline aqueous solution that can be used include a dilute solution of 0.1% by mass to 5% mass of sodium carbonate, a dilute solution of 0.1% by mass to 5% by mass of potassium carbonate, a dilute solution of 0.1% by mass to 5% by mass of sodium hydroxide, and a dilute solution of 0.1% by mass to 5% by mass of sodium tetraborate. pH of the aqueous alkaline solution used for the development may be within a range of 9 to 11, and the temperature of the alkaline solution can be adjusted in accordance with developability of the photosensitive layer. For example, a surfactant, an antifoaming agent, a small amount of organic solvent for promoting development, and the like may be mixed into the alkaline aqueous solution.

Examples of the organic solvent to be used in the alkaline aqueous solution include 3-acetone alcohol, acetone, ethyl acetate, alkoxyethanol having an alkoxy group having 1 to 4 carbon atoms, ethyl alcohol, isopropyl alcohol, betyl alcohol, diethylene glycol monomethyl ether, diethylene glycol monoethyl ether, and diethylene glycol monobutyl ether.

Examples of the organic solvent to be used in the organic solvent developer include 1,1,1-trichloroethane, N-methyl-2-pyrrolidone, N,N-dimethylformamide, cyclohexanone, methylisobutyl ketone, and γ-butyrolactone. From the viewpoint of preventing flaming, water may be added within a range of 1% by mass to 20% by mass to the organic solvent to thereby obtain the organic solvent developer.

### (Other Processes)

The method of forming a resist pattern according to the present embodiment may include a process of further curing the resist pattern by performing heating at about 60° C. to 250° C. or exposure in the exposure amount of 0.2 J/cm² to 10 J/cm² as needed after the uncured portion is removed in the development process.

### [Method of Manufacturing Wiring Substrate]

A method of manufacturing a wiring substrate according to the present embodiment includes a process of performing etching process or plating process on a substrate with a resist pattern formed thereon by the above-described method of forming a resist pattern to thereby form a conductor pattern, and the method may also be configured to include other processes such as the resist pattern removal process and the like as needed.

In the etching process, a conductor layer provided on the substrate is etched and removed using the resist pattern formed on the substrate as a mask to thereby form a conductor pattern. A method of the etching process is appropriately selected in accordance with a conductor layers to be removed. Examples of an etching solution include a copper (II) chloride solution, an iron (II) chloride solution, an alkali etching solution, and hydrogen peroxide-based etching solutions.

In the plating process, plating process is performed on the conductor layer provided on the substrate using the resist pattern formed on the substrate as a mask. The conductor pattern may be formed by removing the resist by removing a resist pattern, which will be described later, after the plating process and further etching the conductor layer covered with the resist. A method of the plating process may be electrolytic plating process.

After the etching process or the plating process, the resist pattern on the substrate is removed. The resist pattern can be peeled off with, for example, an inorganic alkali stripper or an organic alkali stripper. Examples of the inorganic alkali stripper to be used include an aqueous solution of 1% by mass to 10% by mass of sodium hydroxide and an aqueous solution of 1% by mass to 10% by mass of potassium hydroxide. Examples of the organic alkali stripper to be used include amine-based strippers such as ethanolamine, ethylenediamine, and diethylenetriamine and an aqueous solution of tetramethylammonium hydroxide. From the viewpoint of releasability of the thick film resist pattern, an organic alkali stripper may be used.

Examples of a method of removing the resist pattern include a dipping method and a spraying method, and these methods may be used alone or together.

In the case where the resist pattern is removed after the plating process is performed, it is possible to manufacture a desired print wiring board by further performing etching process to etch the conductor layer covered with the resist to form a conductor pattern. A method of the etching process at this time is appropriately selected in accordance with the conductor layer to be removed. For example, the above-described etching solution can be applied.

The method of manufacturing the wiring substrate according to the present embodiment can be applied not only to manufacturing of a single-layer wiring substrate but also to manufacturing of a multilayer wiring substrate and can also be applied to manufacturing of a wiring substrate including a small-diameter through-hole and the like.

### EXAMPLES

Although the present disclosure will be further specifically explained by Examples, the present disclosure is not limited to these Examples.

### [Photosensitive Resin Composition]

Photosensitive resin compositions were prepared by mixing the components in the blending amounts (parts by mass) shown in Table 1 with 4.5 parts by mass of acetone, 16 parts by mass of toluene, and 4 parts by mass of methanol. Note that the blending amounts (parts by mass) of the components shown in Table 1 refer to the masses (solid content) of nonvolatile parts. Details of the components shown in Table 1 are as follows.

### (Component (A))

A1: Ethylene glycol monomethyl ether/toluene solution (solid content: 47% by mass) of copolymer of methacrylic acid/methyl methacrylate/styrene/benzyl methacrylate (mass ratio: 27/5/45/23, Mw: 47000, acid value: 176.1 mgKOH/g, Tg: 107° C.)

### (Component (B))

B1: 2,2-bis(4-(methacryloxypentaethoxy)phenyl) propane (EO average of 10 mol adduct, molecular weight: 804, manufactured by Resonac Corporation, trade name “FA-321M”)

### (Component (C))

BCIM: 2,2′-bis(o-chlorophenyl)-4,4′,5,5′-tetraphenyl-1,2′-biimidazole (manufactured by Hampford Research Inc.)

### (Component (D))

D1: 9,10-diethoxyanthracene (manufactured by Air Water Performance Chemical Inc., trade name: “UVS-1101”)
D2: 9,10-dibutoxyanthracene (manufactured by Air Water Performance Chemical Inc., trade name: “UVS-1331”)

### (Component (F))

TBC: 4-tert-butylcatechol (manufactured by DIC Corporation, trade name: “DIC-TBC”)

### (Other Components)

LCV: Leuco crystal violet (manufactured by Yamada Chemical Co., Ltd.)
MKG: Malachite green (manufactured by Osaka Organic Chemical Industry Ltd.)
SF-808H: mixture of carboxybenzotriazole, 5-amino-1H-tetrazole, and methoxypropanol (manufactured by Sanwa Kasei Corporation)

### [Photosensitive Element]

As a support film, a polyethylene terephthalate film (manufactured by Toray Industries, Inc., trade name: “FB-40”) having a thickness of 16 μm was prepared. The photosensitive resin composition was applied to the support film and was then successively dried with hot air convection driers at 80° C. and 120° C. to form a photosensitive layer having a thickness of 40 μm after the drying. A polyethylene film (manufactured by Tamapoly Co., Ltd., trade name: “NF-15”) was attached as a protective film to the photosensitive layer to obtain a photosensitive element including the support film, the photosensitive layer, and the protective film.

### (Light Transmittance)

After the protective film of the photosensitive element was peeled off, absorption spectra of the photosensitive layer and the support film were measured using an ultraviolet-visible spectrophotometer (manufactured by Hitachi High-Tech Corporation, trade name: “Hitachi spectrophotometer Ut-3310”). The measurement was carried out using a polyethylene terephthalate film (FB-40) as a reference under conditions of a temperature of 20° C., a slit of 2 nm, a scan speed of 300 nm/min, a sampling interval of 0.50 nm, and a wavelength range of 750 nm to 200 nm. The light transmittance of the photosensitive layer was calculated from the absorbance at a wavelength of 405 nm.

### [Evaluation]

The following evaluation was carried out using the photosensitive element. The results are shown in Table 1.

### (Migration Resistance)

After the photosensitive element was stored at 15° C. for 7 days, the protective film was peeled off. An ultraviolet-visible spectrophotometer (U-3310) was used to measure the absorption spectrum of the protective film. Measurement was performed under conditions of a temperature of 20° C., a slit width of 2 nm, a scan speed of 300 nm/min, a sampling interval of 0.50 rim, and a measurement range of 750 nm to 200 nm. The lower numerical value of absorbance of 405 nm derived from the component (D) of the protective film means better migration resistance.

### [Laminate L1]

A copper-clad laminate (manufactured by Resonac Corporation, trade name: “MCL-E-67”) including a glass epoxy material and copper foils (thickness: 16 μm) disposed on both sides thereof was pickled, washed with water, and then dried with an air flow. Next, the copper-clad laminate was heated to 80° C., and the photosensitive element was then laminated on the copper-clad laminate in such a manner that the photosensitive layer was in contact with the copper surface while the protective film was peeled off, thereby obtaining a laminate L1 including the copper-clad laminate, the photosensitive layer, and the support film in order. The lamination was carried out using a heat roll at 110° C. at a pressure-bonding pressure of 0.4 MPa at a roll rate of 1.0 m/min.

### [Laminate L2]

The above-described photosensitive element was laminated on a Cu-sputtered PET film (manufactured by Geomatec Co., Ltd., plate thickness: 125 μm) in such a manner that the photosensitive layer was in contact with the copper surface while the protective film was peeled off, thereby obtaining a laminate L2 including the Cu-sputtered PET film, the photosensitive layer, and the support film in order. The lamination was carried out using a heat roll at 110° C. at a pressure-bonding pressure of 0.4 MPa at a roll rate of 1.0 m/min.

### (Minimum Development Time)

After the laminate L1 was cut into a square (5 cm×5 cm), the support film was peeled off to obtain a test piece. Next, an unexposed photosensitive layer in the test piece was spray-developed at a pressure of 0.18 MPa by using a 1% by mass of aqueous solution of sodium carbonate at 30° C., and a time in which the fact that the unexposed photosensitive layer of equal to or greater than 1 mm had been removed was able to be visually confirmed was regarded as a minimum developing time (MD). As a nozzle in the spray-development, a full cone-type nozzle was used. The distance between the test piece and the nozzle tip was 6 cm, and the test piece and the nozzle were disposed such that the centers thereof coincided with each other. The shorter minimum developing time (unit: second) means better developing property.

### (Sensitivity)

After a Hitachi 41-step tablet was placed on the support film of the laminate L1, the photosensitive layer was exposed through the support film using a direct drawing exposure machine (manufactured by Orc Manufacturing Co., Ltd., trade name: “FDi-Ms”) using a blue-violet laser diode having a wavelength of 405 nm as a light source with an exposure amount (irradiation energy amount) such that the number of remaining steps of the Hitachi 41-step tablet was 15. Sensitivity (photosensitivity) was evaluated on the basis of the exposure amount (unit: mJ/cm²) at this time. The lower exposure amount means higher sensitivity.

### (Adhesion)

The photosensitive layer of the laminate L1 was exposed by the direct drawing exposure machine (FDi-Ms) in an exposure amount in which the number of remaining steps of the Hitachi 41-step tablet was 15 using a drawing pattern with a line width (L)/space width (S) of x/3x (x=3 to 30, unit: μm, interval: 1 μm). Post-exposure bake (PEB) was performed at 80° C. for 30 seconds within 3 minutes after the exposure.

### (Resolution)

The photosensitive layer of the laminate L1 was exposed by the direct drawing exposure machine (FDi-Ms) in an exposure amount in which the number of remaining steps of the Hitachi 41-step tablet was 15 using a drawing pattern with a line width (L)/space width (S) of 3x/x (x=3 to 30, unit: μm, interval: 1 μm). Post-exposure bake (PEB) was performed at 80° C. for 30 seconds within 3 minutes after the exposure.

After the PEB, the support film was peeled off from the laminate L1, the photosensitive layer was exposed, and a 1% by mass of aqueous solution of sodium carbonate was sprayed thereto at 30° C. for a period of time that was twice as long as the minimum developing time to thereby remove an unexposed portion. After the development, a space part (unexposed portion) was removed without any residue, resolution was evaluated by the minimum value (unit: μm) of space widths in a resist pattern in which the line part (exposed portion) was formed without meandering and chipping, and adhesion was evaluated by the minimum value (unit: μm) of the line widths in the resist pattern. The smaller numerical values mean better resolution and adhesion.

### (Round-hole Resolution)

Using a via pattern (via hole pattern) with a round hole opening portion diameter/pitch between round hole centers of x/2x (x=10 to 50, unit: μm, interval: 1 μm), the photosensitive layer of the laminate L2 was exposed by the direct drawing exposure machine (FDi-Ms) in an exposure amount such that the number of remaining steps of the Hitachi 41-step tablet was 15. Post-exposure bake (PEB) was performed at 80° 6 for 30 seconds within 3 minutes after the exposure.

After the PEB, the support film was peeled off from the laminate L2, the photosensitive layer was exposed, and 1% by mass of aqueous solution of sodium carbonate was sprayed thereto at 30° C. for a period of time that was twice as long as the minimum developing time to thereby remove an unexposed portion. The formed via pattern (via hole pattern) was observed with an optical microscope, and round-hole resolution was evaluated on the basis of the value of the smallest via pattern diameter from among the via patterns aligned in a grid pattern that have been clearly and completely removed (opened). The smaller numerical value means better round-hole resolution.

TABLE 1

| | | Example | | | Comparative Example | | | |
|---|---|---|---|---|---|---|---|---|
| | | 1 | 2 | 3 | 1 | 2 | 3 | 4 |
| (A) | A1 | 57 | 57 | 57 | 57 | 57 | 57 | 57 |
| (B) | B1 | 43 | 43 | 43 | 43 | 43 | 43 | 43 |
| (C) | B-CIM | 5 | 5 | 5 | 5 | 5 | 5 | 5 |
| (D) | D1 | 0.40 | 0.25 | 0.25 | 0.54 | — | — | — |
| | D2 | — | — | — | — | 0.65 | 0.48 | 0.30 |
| (E) | TBC | 0.02 | 0.02 | 0.02 | 0.02 | 0.02 | 0.02 | 0.02 |

| | | | | | | | |
|---|---|---|---|---|---|---|---|
| LCV | 0.5 | 0.3 | 0.7 | 0.5 | 0.5 | 0.3 | 0.3 |
| MKG | 0.01 | 0.01 | 0.01 | 0.01 | 0.01 | 0.01 | 0.01 |
| SF-808H | 0.5 | 0.5 | 0.5 | 0.5 | 0.5 | 0.5 | 0.5 |
| Resist | 33.2 | 46.8 | 41.5 | 22.5 | 22.1 | 32.5 | 45.8 |
| transmittance | | | | | | | |
| (%) @405 nm | | | | | | | |
| Absorbance of | 0.042 | 0.038 | 0.038 | 0.038 | 0.075 | 0.053 | 0.060 |
| protective film | | | | | | | |
| @405 nm | | | | | | | |
| Sensitivity | 62 | 86 | 78 | 52 | 52 | 65 | 82 |
| (mJ/cm²) | | | | | | | |
| Minimum | 36 | 36 | 36 | 35 | 35 | 35 | 36 |
| developing time | | | | | | | |
| (second) | | | | | | | |
| Adhesion x/x | 10 | 10 | 10 | 14 | 16 | 16 | 12 |
| (μm) | | | | | | | |
| Resolution 3x/x | 10 | 10 | 10 | 10 | 12 | 10 | 12 |
| (μm) | | | | | | | |
| Round-hole | 13 | 13 | 13 | 16 | 18 | 14 | 13 |
| resolution | | | | | | | |
| (μmφ) | | | | | | | |

### REFERENCE SIGNS LIST

1 Photosensitive element
2 Support film
3 Photosensitive layer
4 Protective film

1. A photosensitive element comprising, in this order: a support film; a photosensitive layer; and a protective film,
wherein the photosensitive layer contains a binder polymer, a photopolymerizable compound, a photopolymerization initiator, and an anthracene-based sensitizer,
the anthracene-based sensitizer includes an anthracene compound having an alkoxy group having 3 or less carbon atoms bonded to 9 and 10-positions of an anthracene ring, and
a thickness of the photosensitive layer is equal to or greater than 30 μm, and a light transmittance of the photosensitive layer at a wavelength of 405 nm is equal to or greater than 25.0% and equal to or less than 95.0%.

2. The photosensitive element according to claim 1, wherein the anthracene compound is at least one kind selected from the group consisting of 9,10-dimethoxyanthracene, 9,10-diethoxyanthracene, and 9,10-dipropoxyanthracene.

3. The photosensitive element according to claim 1, wherein the anthracene compound is 9,10-dimethoxyanthracene or 9,10-diethoxyanthracene.

4. The photosensitive element according to claim 1, wherein a content of the anthracene-based sensitizer is 0.1 parts by mass to 1.0 parts by mass with respect to 100 parts by mass of a total amount of the binder polymer and the photopolymerizable compound.

5. The photosensitive element according to claim 1, wherein the protective film is a polyethylene film.

6. A method of forming a resist pattern, comprising:
forming a photosensitive layer on a substrate using the photosensitive element according to claim 1;
irradiating at least a part of the photosensitive layer with active rays to form a photocured portion; and
removing an unphotocured portion of the photosensitive layer from the substrate to form a resist pattern.

7. A method of manufacturing a wiring substrate, comprising:
performing etching process or plating process on a substrate with a resist pattern formed thereon by the method of forming a resist pattern according to claim 6 to form a conductor pattern.
